(19) United States
(12) Patent Application Publication
(10) Pub. No.: US 2013/0001715 A1
(43) Pub. Date: Jan. 3, 2013

(54) MAGNETORESISTIVE ELEMENT AND MANUFACTURING METHOD OF THE SAME

(75) Inventors: Koji YAMAKAWA, Tokyo (JP); Katsuaki NATORI, Yokohama-Shi (JP); Daisuke IKENO, Yokohama-Shi (JP)

(73) Assignee: KABUSHIKI KAISHA TOSHIBA, Tokyo (JP)

(21) Appl. No.: 13/425,282

(22) Filed: Mar. 20, 2012

(30) Foreign Application Priority Data
Jun. 30, 2011 (JP) 2011-145867

(51) Int. Cl. H01L 29/82; H01L 43/12

(52) U.S. Cl. 257/421; 438/3; 257/E29.323; 257/E43.006

(57) ABSTRACT

In accordance with an embodiment, a magnetoresistive element includes a lower electrode, a first magnetic layer on the lower electrode, a first interfacial magnetic layer on the first magnetic layer, a nonmagnetic layer on the first interfacial magnetic layer, a second interfacial magnetic layer on the nonmagnetic layer, a second magnetic layer on the second interfacial magnetic layer; and an upper electrode layer on the second magnetic layer. Either the first magnetic and interfacial magnetic layers or the second magnetic and interfacial magnetic layers constitute a storage layer. The other layers of the first magnetic and interfacial magnetic layers and the second magnetic and interfacial magnetic layers constitute a reference layer. The lower electrode includes an alloy layer or mixture layer of a precious metal and a transition element or a rare earth element, or comprises a conductive oxide layer.

### CROSS REFERENCE TO RELATED APPLICATIONS

This application is based upon and claims the benefit of priority from the prior Japanese Patent Application No. 2011-145867, filed on Jun. 30, 2011, the entire contents of which are incorporated herein by reference.

### FIELD

Embodiments described herein relate generally to a magnetoresistive element and a manufacturing method of the same.

### BACKGROUND

Recently, a magnetic random access memory (MRAM) that uses a tunneling magnetoresistive (TMR) effect has been developed. A magnetoresistive element that includes a magnetic tunnel junction (MTJ) is used for the magnetic random access memory, and this element has a high magnetoresistance change. A currently studied spin injection writing method uses an in-plane magnetization MTJ film and a perpendicular magnetization MTJ film, and allows the miniaturization of the structure of the magnetoresistive element and the reduction of a current.

Precious metal materials such as Ru, Ir, Pt, and Pd are often used to form the MTJ film. More specifically, the components of the MTJ film include an artificial lattice magnetic film including, for example, Co/Pt or Co/Pd, a crystalline magnetic film including, for example, FePt or FePd, and an Ru spacer film.

However, an Ru, Pt, or Ir film having a thickness equal to or more than the thickness of the above-mentioned films is used for a bottom electrode layer or a cap film layer of an MTJ stack structure. Pure metals are used for these parts even when the influence on the electric and magnetic characteristics of the MTJ element is small and alternative materials can be introduced. The pure metals are difficult to fabricate by RIE or ion beam etching (IBE), and tend to remain as residual when fabricated. Thus, the pure metals easily cause failures such as an element short circuit. Moreover, during a heat treatment, the pure metals may diffuse to a magnetic layer part of the MTJ element, and cause electric characteristic deterioration.

Ta and Si oxide films are used for a hard mask for fabricating the MTJ element because these oxide films are high in fabrication selectivity in regard to the MTJ element. However, the problem is that these films are low in etching selectivity in regard to the RIE and the ion beam etching (IBE) and cause the hard mask to back down and to be easily chipped at the end in the process of fabrication, leading deteriorated shape of the MTJ element and increased size variations.

### BRIEF DESCRIPTION OF THE DRAWINGS

FIG. 1 is a sectional view showing a basic structure of a magnetoresistive element according to Embodiment 1;

FIG. 2 is a sectional view showing a modification of FIG. 1;

FIG. 3A to FIG. 3D are sectional views showing a method of manufacturing a magnetic random access memory including the magnetoresistive element shown in FIG. 1;

FIG. 4A is a sectional view showing a method of manufacturing the magnetoresistive element shown in FIG. 1; and

FIG. 4B is a sectional view showing a modification of the method shown FIG. 4A.

### DETAILED DESCRIPTION

In accordance with an embodiment, a magnetoresistive element includes a lower electrode, a first magnetic layer on the lower electrode, a first interfacial magnetic layer on the first magnetic layer, a nonmagnetic layer on the first interfacial magnetic layer, a second interfacial magnetic layer on the nonmagnetic layer, a second magnetic layer on the second interfacial magnetic layer; and an upper electrode layer on the second magnetic layer. Either the first magnetic and interfacial magnetic layers or the second magnetic and interfacial magnetic layers constitute a storage layer. The other layers of the first magnetic and interfacial magnetic layers and the second magnetic and interfacial magnetic layers constitute a reference layer. The lower electrode includes an alloy layer or mixture layer of a precious metal and a transition element or a rare earth element, or comprises a conductive oxide layer.

Embodiments will now be explained with reference to the accompanying drawings. Like components are given like reference numbers throughout the drawings and repeated explanations thereof are omitted accordingly.

(1) Configuration of Magnetoresistive Element

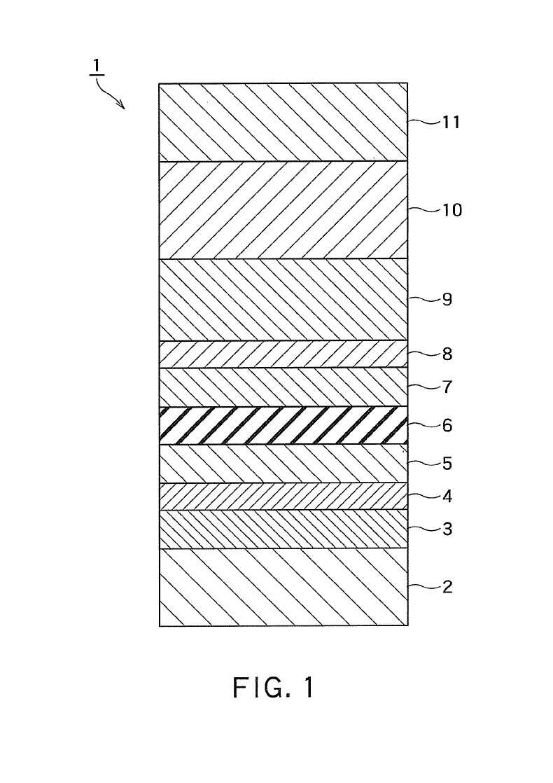

FIG. 1 is a sectional view showing the basic structure of a magnetoresistive element 1 according to Embodiment 1.

The magnetoresistive element 1 shown in FIG. 1 is an element having a perpendicular magnetization film higher in recording density than an in-plane magnetic film. The magnetoresistive element 1 includes a lower electrode 2, a magnetic layer 3, a first metal layer 4, a first interfacial magnetic layer 5, a nonmagnetic layer 6, a second interfacial magnetic layer 7, a second metal layer 8, a magnetic layer 9, a magnetization adjustment layer 10, and an upper electrode 11. In the present embodiment, the magnetic layers 3 and 9 correspond to, for example, first and second magnetic layers, respectively. Either layers of the magnetic layer 3 and the interfacial magnetic layer 5, or the interfacial magnetic layer 7 and the magnetic layer 9 constitute a storage layer. The other layers of the magnetic layer 3 and the interfacial magnetic layer 5, and the interfacial magnetic layer 7 and the magnetic layer 9 constitutes a reference layer. When the magnetoresistive element 1 according to the present embodiment includes, for example, an MTJ structure having the magnetization storage layer at the bottom, the storage layer is provided on the lower electrode 2 as shown in FIG. 1. An alloy layer or mixture layer of a precious metal such as Pt, Ir, or Ru and a transition element such as Ta or a rare earth element is used for the lower electrode 2. Ti, V, Y, W, Mo, or Zr can be selected as the transition element instead of Ta. For example, Yb can be selected as the rare earth element. Here, the alloy layer means a layer in which two or more kinds of metals are mixed at a constant ratio on the atomic level. The mixture layer means a layer including two or more kinds of elements other than the alloy layer.

A structure that uses the crystal orientation of the precious metal allows the orientation of an fcc structure (111) face to be easily obtained. Therefore, when this structure is used, the precious metal can be set to a slightly large amount of 50% or more. The lower electrode 2 can also be made of a conductive oxide. Specific examples of the conductive oxide include an oxide film made of a precious metal such as RuOx or IrOx, and a composite oxide conductive film made of SrRuO₃ or LaNiO₃. When the lower electrode 2 is made of a conductive oxide, the orientation of the magnetization storage layer 3 formed on the lower electrode 2 is improved. As a result, a magnetoresistive element capable of stable operation is provided. When the influence of a foundation structure provided on a substrate should be eliminated in the lower electrode 2, an amorphous metal film including an alloy of Ir and Ta may be provided under the lower electrode 2.

The magnetic layer 3 is a perpendicular magnetic film having its magnetization substantially perpendicular to a film plane, and is variable in magnetization direction. The magnetic layer 3 includes a first metal atom. In the present embodiment, the first metal atom means, for example, a Pt or Pd atom. More specifically, an ordered alloy layer is used for the magnetic layer 3. For example, FePd, FePt, CoPt, or CoPd is used. The thickness of the lower electrode 2 is, for example, about 5 nm. The thickness of the magnetic layer 3 is, for example, about 1 nm. The lower electrode 2 also serves as a layer for controlling the orientation of the magnetic layer 3 formed thereon. The first metal layer 4 is provided on the magnetic layer 3. The first metal layer 4 is made of, for example, Ta, and has a thickness of, for example, about 0.5 nm.

The first interfacial magnetic layer 5 is provided on the first metal layer 4. The first interfacial magnetic layer 5 is formed by using CoFeB as the main component. The first interfacial magnetic layer 5 may include Co, Fe, CoFe, CoFeB, or a stack structure including these materials. The first interfacial magnetic layer 5 has perpendicular magnetization resulting from the exchange coupling between the first interfacial magnetic layer 5 and a perpendicular magnetic film such as the magnetization storage layer 3. The thickness of the first interfacial magnetic layer 5 is, for example, about 1 nm.

The nonmagnetic layer 6 is provided on the first interfacial magnetic layer 5 as a tunnel insulating film. The nonmagnetic layer 6 is an oxide having an NaCl structure, and is preferably formed by selecting a material having a low degree of lattice mismatch between the (100) face of the above oxide and the first interfacial magnetic layer 5. As the nonmagnetic layer 6, an insulating film that is preferentially oriented to a [100] direction can be obtained, for example, by crystal growth on an amorphous CoFeB alloy structure. Although, for example, MgO, CaO, SrO, TiO, VO, or NbO is used for the nonmagnetic layer 6, other materials may be used instead. The thickness of the nonmagnetic layer 6 is, for example, about 1 nm. Due to the small thickness, the area resistance value of the magnetoresistive element 1 is set to about 10 Ωμm² or less.

The second interfacial magnetic layer 7 is provided on the nonmagnetic layer 6. A material similar to the above-mentioned material of the first interfacial magnetic layer 5 is used for the second interfacial magnetic layer 7. The second interfacial magnetic layer 7 has perpendicular magnetization resulting from the exchange coupling between the second interfacial magnetic layer 7 and a perpendicular magnetic film such as the magnetic layer 9. The thickness of the second interfacial magnetic layer 7 is, for example, about 1 nm. The second metal layer 8 made of, for example, Ta is provided on the second interfacial magnetic layer 7. The thickness of the second metal layer 8 is, for example, about 0.5 nm.

The magnetic layer 9 is provided on the second metal layer 8. The magnetic layer 9 is a perpendicular magnetic film having its magnetization substantially perpendicular to a film plane. The magnetization direction of the magnetization reference layer 9 is fixed to one direction. The magnetic layer 9 includes a second metal atom. For example, a disordered alloy, an ordered alloy, or an artificial lattice is used to form the magnetization reference layer 9 which is a perpendicular magnetic film. An alloy of Co and an element such as Cr, Ta, Nb, V, W, Hf, Ti, Zr, Pt, Pd, Fe, or Ni is used as the disordered alloy. For example, a CoCr alloy or a CoPt alloy is used. An alloy of Fe, Co, or Ni and Pt or Pd is used as the ordered alloy. Such an alloy includes, for example, FePt, FePd, or CoPt. An Fe, Co, or Ni element, a Cr, Pt, Pd, Ir, Rh, Ru, Os, Re, or Au element, or a stack of alloys of such elements is used as the artificial lattice. For example, Co/Pd, Co/Pt, or Co/Ru is used. It is also possible to use an alloy material including a transition metal such as Tb, Dy, or Gd, TbFe, TbCo, DyTbFeCo, or TbCoFe. The thickness of the magnetic layer 9 is, for example, about 6 nm.

The magnetization adjustment layer 10 is provided on the magnetic layer 9. The magnetization adjustment layer 10 is an antiferromagnetic film provided to fix the magnetization of the magnetic layer 9 to a predetermined direction. For example, FeMn, NiMn, PtMn, PdMn, PtPdMn, RuMn, OsMn, IrMn, or CrPtMn which is an alloy of Fe, Ni, Pt, Pd, Ru, Os, Ir and Mn is used for the magnetization adjustment layer 10. The thickness of the magnetization adjustment layer 10 is, for example, about 8 nm.

The upper electrode (or cap layer) 11 is provided on the magnetization adjustment layer 10. A film which is made of an alloy of a precious metal and a transition element or a rare earth element such as an alloy of Ru and Ta or which is made of a mixture layer is used for the upper electrode 11. The thickness of the upper electrode 11 is, for example, about 5 nm.

An antioxidant film layer (e.g., Ru and Ta, Ru and Ni, Ru and Ti, or Ir and Ti) and a conductive oxide electrode may be combined together for use as the upper electrode 11. An oxide film made of a precious metal such as RuOx or IrOx, or a composite oxide conductive film made of SrRuO₃ or LaNiO₃ can be used for the conductive oxide film. The conductive oxide layer is low in etching rate in RIE or IBE, and is therefore improved in etching selectivity in regard to an MTJ film. This can inhibit the size variations of MTJ elements. As a result, electric characteristic variations of MTJ elements can be inhibited.

In the present embodiment, both the lower electrode 2 and the upper electrode 11 include an alloy layer or mixture layer of a precious metal and a transition element or a rare earth element, or include a combination of an antioxidant film layer and a conductive oxide. However, taking into account the difference of fabrication quality and the contamination influence, the upper electrode 11 alone may include an alloy layer or mixture layer of a precious metal and a transition element or a rare earth element, or include a combination of an antioxidant film layer and a conductive oxide.

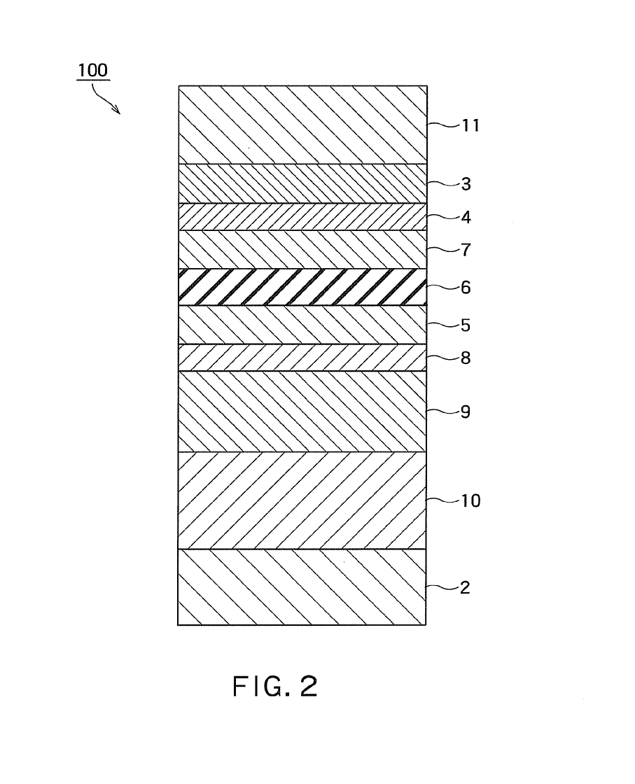

The magnetoresistive element 1 shown in FIG. 1 is structured so that the lower electrode 2, the magnetic layer 3, the first metal layer 4, the first interfacial magnetic layer 5, the nonmagnetic layer 6, the second interfacial magnetic layer 7, the second metal layer 8, the magnetic layer 9, the magnetization adjustment layer 10, and the upper electrode 11 are stacked in this order from the lower side to the upper side. Thus, the magnetization of the magnetic layer 3 can be precisely controlled. Otherwise, as in the structure of a magnetoresistive element 100 according to a modification shown in FIG. 2, the lower electrode 2, the magnetization adjustment layer 10, the magnetic layer 9, the second metal layer 8, the first interfacial magnetic layer 5, the nonmagnetic layer 6, the second interfacial magnetic layer 7, the first metal layer 4, the magnetic layer 3, and the upper electrode 11 may be stacked in this order from the lower side to the upper side. The same applies to Embodiment 2 described below.

(2) Method of Manufacturing Magnetoresistive Element

Now, a method of manufacturing a magnetic random access memory including the magnetoresistive element 1 is illustrated to describe a method of manufacturing the magnetoresistive element 1 according to Embodiment 1 below.

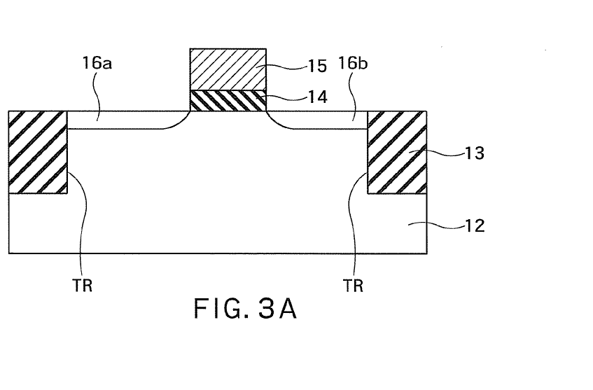

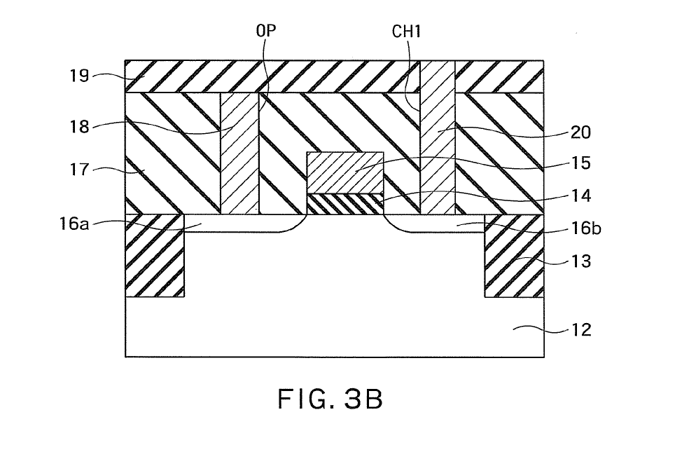

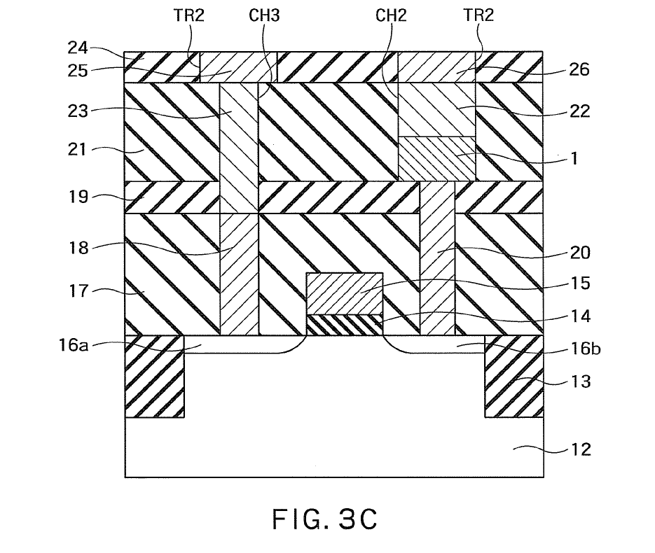

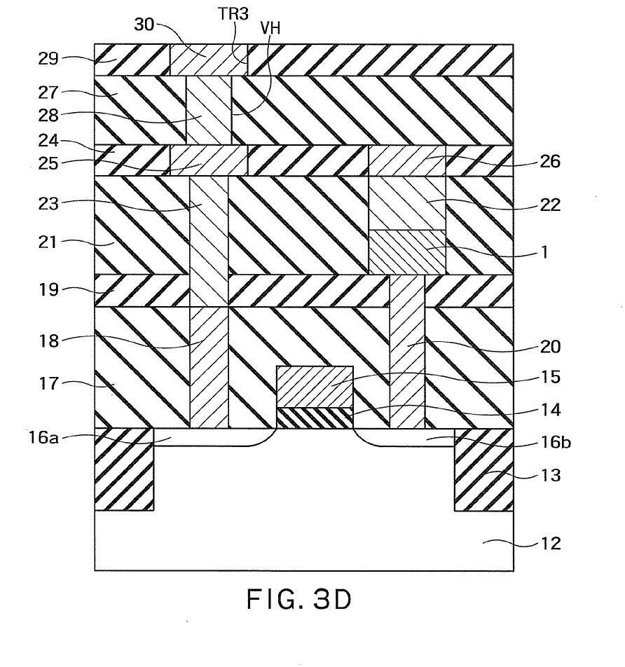

FIG. 3A to FIG. 3D are sectional views showing the method of manufacturing the magnetic random access memory including the magnetoresistive element shown in FIG. 1.

First, as shown in FIG. 3A, an element isolation trench TR is formed in the surface layer of a semiconductor substrate 12, and the element isolation trench TR is filled with an insulating film such as a silicon oxide film. Thereby, an element isolation insulating film 13 having a shallow trench isolation (STI) structure is formed. A gate insulating film 14 and a gate electrode 15 are then formed. A source region 16a and a drain region 16b are then formed by ion implantation and annealing, thereby forming a select transistor. The process described above can be carried out by using an existing technique.

As shown in FIG. 3B, for example, a silicon oxide film is then formed all over the select transistor as a first insulating film 17 by plasma chemical vapor deposition (CVD). Furthermore, an opening OP is formed by a photolithographic method and reactive ion etching (RIE) so that a part of the source region 16a is exposed.

A W (tungsten) film is then formed all over in the opening OP by a sputtering method or by CVD under forming gas atmosphere. Furthermore, this W film is planarized by chemical mechanical polishing (CMP). In this way, a first contact plug 18 that communicates with the source region 16a is formed in the silicon oxide film 17. The gate electrode 15 is connected to an unshown word line. The source region 16a is connected to an unshown bit line.

A CVD nitride film 19 is then formed all over the silicon oxide film 17 and the first contact plug 18 by the CVD method. Furthermore, a contact hole CH1 that communicates with the drain region 16b is formed, and a W film is formed. The W film is then planarized by CMP to form a second contact plug 20. The second contact plug 20 serves as a leader line to connect the drain region 16b to the magnetoresistive element 1.

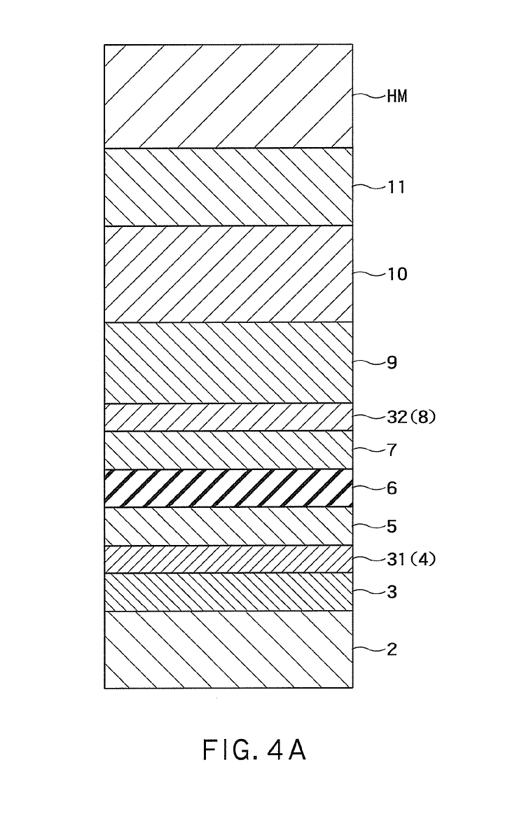

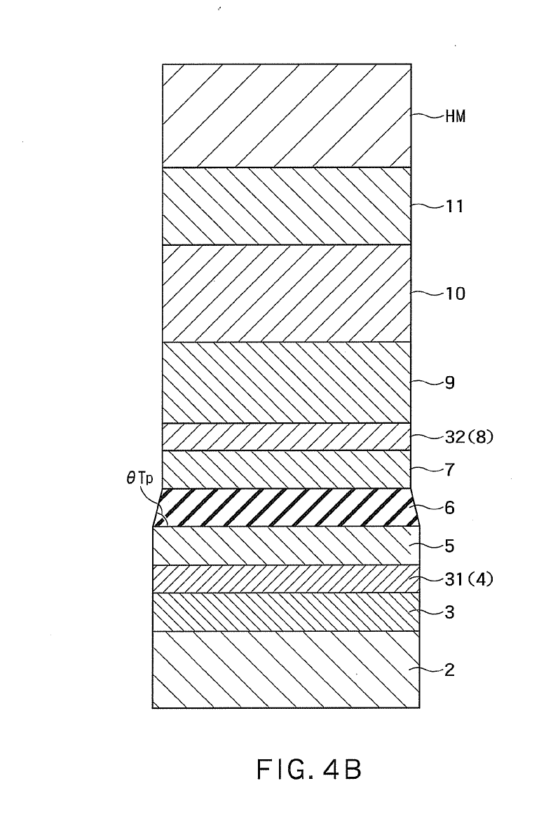

The magnetoresistive element 1 is then formed. A method of forming the magnetoresistive element 1 is specifically described below with reference to FIG. 4A and FIG. 4B.

An Ir/Ta alloy layer of about 5 nm in thickness is formed on the second contact plug 20 as a lower electrode 2. Other materials that may be used for the lower electrode 2 include an alloy or mixture of Pt or Ru and Ta, Ni, Ti, or W. Thus, an alloy or mixture of a precious metal and a transition element or a rare earth element is used as the lower electrode 2. Consequently, the lower electrode 2 is higher in fabrication quality and is less likely to remain as residual in a fabrication process than when the lower electrode 2 is made of a precious metal alone. This can prevent contamination.

The lower electrode 2 can be made of a conductive oxide instead. Specific examples of the conductive oxide include an oxide film made of a precious metal such as RuOx or IrOx, and a composite oxide conductive film made of SrRuO₃ or LaNiO₃. When the lower electrode 2 is made of a conductive oxide, the orientation of a magnetization storage layer 3 formed on the lower electrode 2 is improved. If a thin precious metal film made of, for example, Ir or Pt is stacked, a crystallized film is easily obtained.

A CoPd layer of about 1 nm in thickness is then formed on the lower electrode 2 as the magnetic layer 3. Furthermore, for example, a Ti layer of about 0.5 nm in thickness is formed on the magnetic layer 3 as a diffusion prevention layer 31. An atom selected from the group consisting of Ta, V, Y, Zr, and Yb is otherwise used as the material of the diffusion prevention layer 31.

An amorphous CoFeB layer 5 of about 1 nm in thickness is then formed on the diffusion prevention layer 31 to form a first interfacial magnetic layer 5.

A partly crystalline tunnel film made of MgO of about 1 nm in thickness is then formed on the CoFeB layer 5 as a nonmagnetic layer 6. An amorphous CoFeB layer 7 of about 1 nm in thickness is formed to form a second interfacial magnetic layer 7 on the nonmagnetic layer 6.

Ti is then deposited on the CoFeB layer 7 to form a second metal layer 32 of about 0.5 nm in thickness. Thereon, an FePd layer of about 6 nm in thickness is formed as a magnetic layer 9. Instead of Ti, the second metal layer 32 may include an atom selected from the group consisting of Ta, V, Y, Zr, and Yb.

A CoPd film of about 8 nm in thickness is then formed on the magnetic layer 9 as the magnetization adjustment layer 10. An RuTa alloy layer of about 5 nm in thickness is formed on the magnetization adjustment layer 10 as an upper electrode 11.

Thus, an alloy or mixture of a precious metal and a transition element or a rare earth element is used for the upper electrode 11. Consequently, the upper electrode 11 is higher in fabrication quality and is less likely to remain as residual in a fabrication process than when the upper electrode 11 is made of a precious metal alone. This can prevent contamination.

For example, Ir and Ta, Ru and Ni, or Ru and Ti are otherwise used as the material of the upper electrode 11. An alloy or mixture of a precious metal and a transition element or a rare earth element is used for the upper electrode 11. Consequently, the upper electrode 11 is higher in fabrication quality and is less likely to remain as residual in a fabrication process than when the upper electrode 11 is made of a precious metal alone. This can prevent contamination. As a result, a magnetoresistive element capable of stable operation is provided. The upper electrode 11 may be formed immediately on the magnetic layer 9 without forming the magnetization adjustment layer 10.

The layers constituting the magnetoresistive element 1 are formed through the manufacturing process described above. It should be understood that the layers constituting the magnetoresistive element 1 are not exclusively stacked in the above-mentioned order. The lower electrode 2, the magnetization adjustment layer 10, the magnetic layer 9, the first metal layer 31, the first CoFeB layer 5, the nonmagnetic layer 6, the second CoFeB layer 7, the second metal layer 32, the magnetic layer 3, and the upper electrode 11 may be stacked in this order.

In the process described above, the lower electrode 2, the magnetic layer 3, the first metal layer 31, the first CoFeB layer 5, the nonmagnetic layer 6, the second CoFeB layer 7, the second metal layer 32, the magnetic layer 9, the magnetization adjustment layer 10, and the upper electrode 11 can be formed by, for example, the sputtering method.

Annealing is then carried out in a vacuum at 300° C. to 350° C. for about one hour. This facilitates the crystallinity of the MgO film that constitutes the nonmagnetic layer 6. Moreover, B (boron) is discharged by the annealing from the first CoFeB layer 5 and the second CoFeB layer 7 to the first and second metal layers 31 and 32, and becomes CoFe crystal to serve as the first and second interfacial magnetic layers 5 and 7, respectively. This annealing may be carried out under nitrogen atmosphere. Lamp annealing may be carried out in a vacuum at 400° C. for about 10 to 30 seconds by rapid thermal annealing (RTA).

As a result of this annealing, alloys are formed by an atom such as a Pd atom to constitute the magnetic layer 3 and the magnetic layer 9 and by atoms such as Ti atoms to constitute the first metal layer 31 and the second metal layer 32. These alloys serve as the first metal layer 4 and the second metal layer 8, respectively (see FIG. 1). Thus, it is possible to obtain the magnetoresistive element 1 capable of inhibiting the diffusion of the atoms to the nonmagnetic layer 6 and capable of stable operation even after a thermal treatment.

On the structure of the magnetoresistive element 1 formed by the method described above, a hard mask HM made of a conductive oxide is formed so that the magnetoresistive element 1 on the second contact plug 20 will remain. The upper electrode 11, the magnetization adjustment layer 10, the magnetic layer 9, the second metal layer 8, the second interfacial magnetic layer 7, the nonmagnetic layer 6, the first interfacial magnetic layer 5, the first metal layer 4, the magnetic layer 3, and the lower electrode 2 are etched and thereby fabricated by a lithographic method and ion beam etching (IBE) or RIE. Here, specific examples of the conductive oxide to be used as the hard mask HM include an oxide film made of a precious metal such as RuOx or IrOx, and a composite oxide conductive film made of SrRuO₃ or LaNiO₃. However, as this film is an oxide, a film in contact with the oxide is preferably a layer that includes at least a precious metal. The conductive oxide hard mask can have a high etching selectivity in regard to the IBE, and shows a high function in the quality of element fabrication.

Thus, an alloy or mixture of a precious metal and a transition element or a rare earth element, or a conductive oxide is also used for the hard mask HM. Consequently, the hard mask HM is higher in fabrication quality and is less likely to remain as residual in a fabrication process than when the hard mask HM is made of a precious metal alone. This can prevent contamination. As a result, a magnetoresistive element capable of stable operation is provided.

However, a precious metal and the like are used in the magnetoresistive element 1, so that when, for example, the MgO film used as the nonmagnetic layer 6 is thin, residual adheres to the side surface of the nonmagnetic layer 6 due to the etching, and a leak current might be generated in the magnetoresistive element 1. Accordingly, it is necessary to control a taper angle θtp in the part of the nonmagnetic layer 6. This taper angle θtp is preferably 80 degrees or more, in particular, 85 degrees or more, as shown in FIG. 4B.

An oxygen or hydrogen diffusion prevention layer (not shown) is then formed by atomic layer deposition (ALD), CVD, or physical vapor deposition (PVD). For example, SiN or AlOx can be used for this prevention film.

As shown in FIG. 3C, for example, a silicon oxide film 21 is then formed by the CVD method on the CVD nitride film 19 as a second insulating film to cover the magnetoresistive element 1.

Furthermore, a third contact plug 22 connected to the upper electrode 11 of the magnetoresistive element 1 is formed, and a fourth contact plug 23 connected to the second contact plug 18 is formed.

In this case, the silicon oxide film 21 is fabricated by the lithographic method and RIE so that contact holes CH2 and CH3 are formed. The contact holes are then filled with Al, and the contact plugs are formed by CMP.

A silicon oxide film 24 is then formed on the silicon oxide film 21, the third contact plug 22, and the fourth contact plug 23. Furthermore, the silicon oxide film 24 is fabricated by the lithographic method and RIE so that the third contact plug 22 and the fourth contact plug 23 are exposed, thereby forming a trench TR2 for forming first wiring lines 25 and 26. The trench TR2 is then filled with Al, and the first wiring lines 25 and 26 are formed by CMP.

As shown in FIG. 3D, an insulating film 27 is then formed on the silicon oxide film 24 and the first wiring lines 25 and 26. Furthermore, the insulating film 27 is fabricated by the lithographic method and RIE so that the first wiring line 25 is exposed, thereby forming a via hole VH. This via hole VH is then filled with Al, and a via plug 28 is formed by CMP.

A silicon oxide film 29 is then formed on the insulating film 27 and the via plug 28. Furthermore, the silicon oxide film 29 is fabricated by the lithographic method and RIE so that the via plug 28 is exposed, thereby forming a trench TR3. The trench TR3 is then filled with Al, and a second wiring line 30 is formed by CMP.

A Cu wiring line may be formed by using a damascene process. In this case, a barrier film and a seed layer made of, for example, SiN, Ta, TaN, Ru, or Cu are formed, and wiring lines are formed by a filling process using Cu plating.

The magnetic random access memory including the magnetoresistive element according to Embodiment 1 is provided by the process described above.

Although the present embodiment has been described on the assumption that the first metal layer 4 and the second metal layer 8 are provided, one of the first metal layer 4 and the second metal layer 8 does not have to be provided. In this case, manufacturing costs can be reduced by reducing the manufacturing process of the magnetic random access memory.

The diffusion prevention layers 31 and 32 inhibit the diffusion of an atom such as a Pd atom constituting the magnetic layer 3 and the magnetic layer 9 to the nonmagnetic layer 6 in the annealing. Therefore, it is possible to obtain the magnetoresistive element 1 capable of stable operation even after a thermal treatment.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A magnetoresistive element comprising:
a lower electrode;
a first magnetic layer on the lower electrode;
a first interfacial magnetic layer on the first magnetic layer;
a nonmagnetic layer on the first interfacial magnetic layer;
a second interfacial magnetic layer on the nonmagnetic layer;
a second magnetic layer on the second interfacial magnetic layer; and
an upper electrode layer on the second magnetic layer,
wherein the first magnetic and interfacial magnetic layers and the second magnetic and interfacial magnetic layers are one and the other of a storage layer and a reference layer, and
the lower electrode comprises an alloy layer or mixture layer of a precious metal and a transition element or a rare earth element, or comprises a conductive oxide layer.

2. The element of claim 1,
wherein the upper electrode comprises an alloy layer or mixture layer of a precious metal and a transition element or a rare earth element.

3. The element of claim 1,
wherein the alloy layer or mixture layer comprises an alloy or mixture of an element selected from the group consisting of Ta, Ti, V, Y, W, Mo, Zr, and Yb and a precious metal.

4. The element of claim 1,
wherein the conductive oxide comprises an oxide film made of a precious metal comprising RuOx or IrOx, and a composite oxide conductive film comprising SrRuO₃ or LaNiO₃.

5. The element of claim 1, further comprising an amorphous metal film under the lower electrode.

6. The element of claim 1,
wherein the first and second magnetic layers are ordered alloy layers comprising a first metal atom, and have magnetization substantially perpendicular to a film plane.

7. The element of claim 6, wherein
the first interfacial magnetic layer has perpendicular magnetization resulting from the exchange coupling between the first interfacial magnetic layer and the first magnetic layer.

8. The element of claim 6,
wherein the second interfacial magnetic layer has perpendicular magnetization resulting from the exchange coupling between the second interfacial magnetic layer and the second magnetic layer.

9. The element of claim 1,
wherein the nonmagnetic layer is an oxide having an NaCI structure, and is constituted by selecting a material having a low degree of lattice mismatch between a (100) face of the above oxide and the first interfacial magnetic layer.

10. The element of claim 1,
wherein the second magnetic layer is formed by using a disordered alloy, an ordered alloy, or an artificial lattice.

11. The element of claim 1, further comprising an antiferromagnetic film which fixes the magnetization of the second magnetic layer to a predetermined direction between the second magnetic layer and the upper electrode layer.

12. The element of claim 1,
wherein the upper electrode comprises a conductive oxide layer, or a combination of a conductive oxide film and an antioxidant film.

13. The element of claim 1,
wherein the nonmagnetic layer is in a tapered shape having a taper angle of 80 degrees or more.

14. A method of manufacturing a magnetoresistive element, the method comprising:
forming a lower electrode layer on a substrate;
forming a first magnetic layer on the lower electrode layer;
forming a first interfacial magnetic layer on the first magnetic layer,
forming a nonmagnetic layer on the first interfacial magnetic layer,
forming a second interfacial magnetic layer on the nonmagnetic layer;
forming a second magnetic layer on the second magnetic layer;
forming an upper electrode layer on the second magnetic layer; and
forming a hard mask on the upper electrode, and fabricating the upper electrode layer, the second magnetic layer, the second interfacial magnetic layer, the nonmagnetic layer, the first interfacial magnetic layer, the first magnetic layer, and the lower electrode,
wherein the first magnetic and interfacial magnetic layers and the second magnetic and interfacial magnetic layers are one and the other of a storage layer and a reference layer, and
the hard mask is made of an alloy layer or mixture layer of a precious metal and a transition element or a rare earth element, or made of a conductive oxide layer.

15. The method of claim 14,
wherein the lower electrode is made of an alloy layer or mixture layer of a precious metal and a transition element or a rare earth element, or made of a conductive oxide layer.

16. The method of claim 14,
wherein the upper electrode is made of an alloy layer or mixture layer of a precious metal and a transition element or a rare earth element.

17. The method of claim 14,
wherein the upper electrode is made of a conductive oxide layer, or a combination of a conductive oxide film and an antioxidant film.

18. The method of claim 14,
wherein the first interfacial magnetic layer is made of an amorphous layer, and
the nonmagnetic layer is made of an insulating film that is preferentially oriented to a [100] direction by crystal growth on the amorphous layer.

19. The method of claim 14, further comprising controlling the taper angle of the nonmagnetic layer so that the taper angle is 80 degrees or more.

20. The method of claim 14, further comprising forming first and second diffusion prevention layers between the first magnetic layer and the first interfacial magnetic layer and between the first interfacial magnetic layer and the first magnetic layer.
